(19) United States
(12) Patent Application Publication
(10) Pub. No.: US 2004/0094316 A1
(43) Pub. Date: May 20, 2004

(54) Electromagnetic radiation exposure protection mechanism

(75) Inventors: Hiroki Ohno, Tokyo (JP); Hiroshi Omori, Tokyo (JP)

Correspondence Address: MORGAN LEWIS & BOCKIUS LLP, 1111 PENNSYLVANIA AVENUE NW, WASHINGTON, DC, 20004, US

(73) Assignee: Uniden Corporation

(21) Appl. No.: 10/330,494

(22) Filed: Dec. 30, 2002

(30) Foreign Application Priority Data
Nov. 20, 2002 (JP) 2002-336543

(51) Int. Cl. H05K 9/00

(52) U.S. Cl. 174/35 R

(57) ABSTRACT

An object of the present invention is to obtain a specific absorption rate that is within the legally allowable values, without lowering the radio-wave emission level of a wireless telecommunications device. In order to achieve this object, an electromagnetic radiation absorption protection mechanism according to the present invention is constructed so as to be able to be attached to and detached from the wireless telecommunications device, and is provided with a spacer to ensure a prescribed distance between the wireless telecommunications device and the human body. The spacer functions as a mechanism that protects the human body from the absorption of electromagnetic radiation. The height of the spacer is adjusted so that the actual measurement value of the specific absorption rate is less than the upper limit of legally allowable values when the wireless telecommunications device with a belt clip attached thereto is placed in proximity to a phantom body with the spacer interposed between the device and the body.

### BACKGROUND OF THE INVENTION

1. Field of the Invention

The present invention relates to technology to protect the human body from exposure to electromagnetic radiation from wireless telecommunications devices, and more particularly to improving technology for the purpose of protecting the body from such exposure without lowering the radio emission level.

2. Description of the Related Art

In recent years, along with the rapid spread of personal wireless devices such as mobile phones, there has been concern regarding the local effects on the human body of electromagnetic radiation from such wireless telecommunications devices. In response to this, the Ministry of Public Management, Home Affairs, Posts and Telecommunications, in the Telecommunications Technology Council report, has prescribed the Specific Absorption Rate (SAR) as the index for evaluating the effects of electromagnetic radiation on the human body. The SAR shows the amount of electric power absorbed per unit mass of human tissue exposed to electromagnetic radiation (W/kg). Since high frequency devices such as cordless phones use highly directional planar antennas, it is necessary to control the amount of local exposure to radiation by the human body so that it falls below the prescribed value. Japanese Patent Application Laid-Open No. 2002-199077 discloses technology that is improved so as to reduce the amount of radiation that a person's head is exposed to, and enable the desired SAR to be obtained, by providing an electromagnetic radiation absorption layer inside the wireless telecommunications device, comprised of ferrite, permalloy, sendust, stainless steel, silicon steel, amorphous iron alloys and the like.

However, since the thickness of the electromagnetic radiation absorption layer must be at least 2 mm-3 mm, in wireless telecommunications devices where there is demand for developing thinner and lighter models, the provision of such an electromagnetic radiation absorption layer does not result in a desirable construction. A means to lower the radio-wave emission level of the device is another possibility as a technique to protect against electromagnetic radiation. However, such a method is not desirable since in order to achieve the desired call distance it is necessary to take measures to protect against electromagnetic radiation without lowering the device's radio-wave emission level. When wireless telecommunications devices are carried on one's person, they are often in close contact with the body, and therefore it is difficult to reduce the amount of electromagnetic radiation absorbed by the body by distancing the antenna from the body.

### SUMMARY OF THE INVENTION

Therefore, an object of the present invention is to propose technology that protects the human body from the absorption of electromagnetic radiation, which is able to obtain a desired specific absorption rate without lowering the radio-wave emission level of the wireless telecommunications device.

A further object of the present invention is to propose technology that protects the human body from the absorption of electromagnetic radiation, which is able to obtain a desired specific absorption rate without compromising the external appearance design of the wireless telecommunications device.

A further object of the present invention is to reduce the amount of absorption of electromagnetic radiation by the human body when a wireless telecommunications device is carried on one's person.

In order to achieve the foregoing objects, the electromagnetic radiation exposure protection mechanism according to the present invention is structured so that it is able to be attached to and detached from the wireless telecommunications device, and comprises a spacer that ensures a prescribed distance between the wireless telecommunications device and the body. According to this construction, since a prescribed distance can be ensured between the wireless telecommunications device and the body, the prescribed specific absorption rate can be obtained without lowering the radio-wave emission level of the wireless telecommunications device. Further, since the electromagnetic radiation exposure protection mechanism is provided with a mechanism that protects the human body from the absorption of electromagnetic radiation, it is able to obtain the desired specific absorption rate without compromising the external appearance design of the wireless telecommunications device.

Preferably, the above-mentioned spacer has its height adjusted so that the actual measurement value of the specific absorption rate is less than the upper limit of legally allowable values when the wireless telecommunications device with the electromagnetic radiation exposure protection mechanism attached thereto is placed in proximity to a phantom body with the spacer between the device and the body. According to this construction, the specific absorption rate of the wireless telecommunications device can be set less than the upper limit of the legally allowable values.

Preferably, the wireless telecommunications device is provided with a planar antenna having electromagnetic directivity, and the spacer is formed in a direction approximately parallel to the direction of the electromagnetic radiation emanating from the wireless telecommunications device. According to this construction, the desired specific absorption rate can be obtained while enhancing freedom of the wireless telecommunications device's appearance design.

Preferably, the electromagnetic radiation exposure protection mechanism is constructed as a belt clip. According to this construction, since a radiation exposure protection function can be added to a belt clip used to carry wireless telecommunications devices, enhanced convenience can be provided.

### BRIEF DESCRIPTION OF THE DRAWINGS

FIG. 1 is an explanatory diagram of a belt clip provided with an electromagnetic radiation absorption protection mechanism according to the present embodiment.

### DESCRIPTION OF THE PREFERRED EMBODIMENTS

The present embodiment is explained below, with reference to the drawing.

A belt clip provided with a function of protecting the human body from the absorption of electromagnetic radiation is described as one example of an electromagnetic radiation absorption protection mechanism according to the present invention, however the present invention is not limited to this and can be applied to an accessory such as a carrying case or the like that is constructed so that it can be attached to and detached from the wireless telecommunications device. Further, it is not limited to being an accessory in this way, but maybe formed as a specialty product, designed for the purpose of protection against absorption of electromagnetic radiation from the wireless telecommunications device.

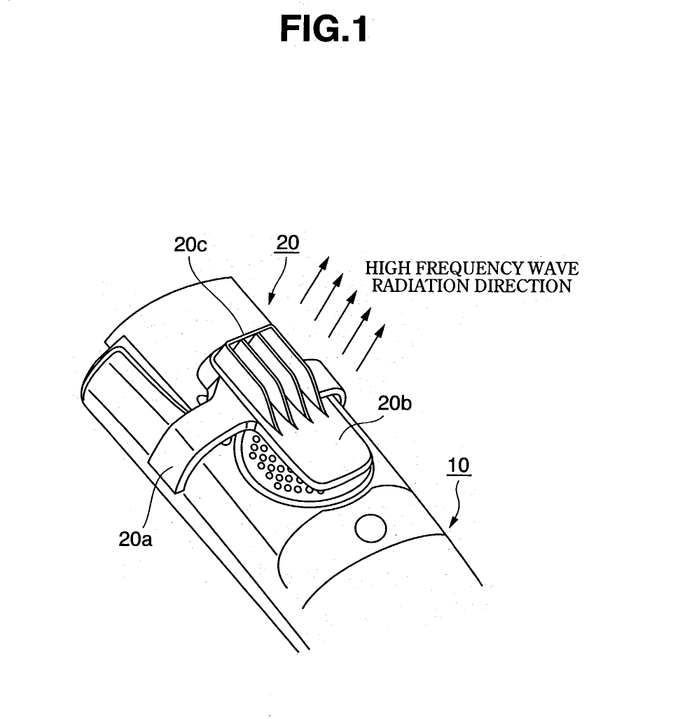

FIG. 1 is an explanatory diagram of a belt clip provided with an electromagnetic radiation absorption protection mechanism. The belt clip 20 provided with this mechanism is designed to allow users to carry a wireless telecommunications device 10 with them when they are not in a call by hooking it to their waist or the like, and can also be used as an accessory for the wireless telecommunications device 10. For the wireless telecommunications device 10, a cordless telephone handset is the most suitable. The belt clip 20 is constructed so that it is able to be removably attached to the wireless elecommunications device 10, and comprises a band 20a as means to grip the body of the wireless telecommunications device 10, a base 20b joining to the fixed end of the band 20a, and a spacer 20c provided in an upright position on the base 20b. It is desirable to form the band 20a, the base 20b and the spacer 20c all out of a material that does not absorb much electromagnetic radiation.

For the material comprising the belt clip 20, it is desirable to use as the principal constituent a material with a dielectric constant close to 1 and having appropriate mechanical strength, flexibility, heat resistance and water resistance to be used as the belt clip 20, such as acrylonitrile butadiene styrene (ABS), for example. By making the dielectric constant of the belt clip 20 nearly the same value as the dielectric constant of air, the effects on the electric field distribution of the area around the belt clip can be reduced. For the specific material composition of the belt clip 20, it may be comprised so as to achieve the desired low dielectric constant by using an ABS copolymer as the main constituent and adding a particular type of substance thereto.

The spacer 20c functions as the mechanism that protects the human body from the absorption of electromagnetic radiation and its specific form is not particularly limited, however it is desirable to form it in a direction that does not intersect with the radiation direction of the high frequency radio waves, in other words, in a direction that does not obstruct the electromagnetic radiation. When a planar inverted F antenna, a microstrip antenna or other such planar antenna is used as the antenna of the wireless telecommunication device 10, since the radiated waves become linearly polarized waves, it is desirable to form the spacer 20c parallel to the polarization direction at approximately even intervals. Further, for the shape of the spacer 20c, it is desirable that it be formed as plates, plate-like projections, rods or the like. By forming the spacer 20c in such away, electromagnetic absorption in the spacer 20c can be reduced as much as possible. It is desirable that the height of the spacer 20c be set at an appropriate value so that it is able to keep the local radiation exposure to human tissue within the desired SAR values. More specifically, the height of the spacer 20c may differ according to the level of electromagnetic radiation, the composition and form of the belt clip 20, the rate of radio-wave absorption within the wireless telecommunications device, the required SAR value and the like. However, in view of the fact that when users make phone calls, many put the wireless telecommunications device 10 close to their head, it is desirable to set the height so that a value is obtained that is less than the upper limit of legally allowable values of electromagnetic radiation absorption energy per phantom unit mass when the wireless telecommunications device 10 with the belt clip 20 according to the present embodiment attached thereto is placed in proximity to a phantom head, ensuring a prescribed distance between the antenna inside the wireless telecommunications device 10 and the phantom head.

According to this structure, when the wireless telecommunications device 10 with the belt clip 20 attached is carried on one's person, since the spacer 20c is interposed between the body and the wireless telecommunications device 10, at least a distance corresponding to the height of the spacer 20c can be ensured between the wireless telecommunications device 10 and the body. Consequently, since the desired SAR value can be obtained without lowering the radio-wave level emitted from the wireless telecommunications device 10, freedom of circuit design can be enhanced. For example, it is possible to use a highly directional planar antenna such as a planar inverted F antenna, a microstrip antenna or the like as the antenna for the wireless telecommunications device 10. Further, according to the present embodiment, a mechanism that protects the human body from the absorption of electromagnetic radiation is provided on the belt clip itself, which is an accessory to the wireless telecommunications device 10, it is unnecessary to equip the wireless telecommunications device itself with a mechanism to protect the human body from the absorption of electromagnetic radiation, thereby enhancing freedom of external appearance design of the wireless telecommunications device 10, and customer needs can be fulfilled at the same time as fulfilling the prescribed SAR value.

In an experiment conducted by the present inventor, the wireless telecommunications device 10 without the belt clip 20 attached was brought in close contact with a phantom head, and the electromagnetic absorption energy amount per 1 g of phantom was measured as 6.42 W/kg. Further, the wireless telecommunications device 10 having a belt clip without the spacer 20c attached was brought in close contact with a phantom head, and the electromagnetic absorption energy amount per 1 g of phantom was measured as 3.55 W/kg. On the other hand, when the wireless telecommunications device 10 attached with the belt clip 20 provided with a spacer 20c having a height of 15 mm according to the present embodiment was brought in close contact with a phantom head, the electromagnetic absorption energy amount per 1 g of phantom was measured as 1.18 W/Kg. This is less than the upper limit of legally allowable values of electromagnetic absorption energy, which is 2.0 W/Kg per 10 g of human tissue. Note that the radio-wave emission level of the wireless telecommunications device 10 was set at +16 dBm.

What is claimed is:

1. An electromagnetic radiation exposure protection mechanism that is able to be attached to and detached from a wireless telecommunications device, said electromagnetic radiation exposure protection mechanism comprising a spacer to ensure a prescribed distance between the wireless telecommunications device and a human body.

2. The electromagnetic radiation exposure protection mechanism according to claim 1, wherein the height of said spacer is adjusted so that the actual measurement value of the specific absorption rate is less than the upper limit of legally allowable values when said wireless telecommunications device with said electromagnetic radiation exposure protection mechanism attached thereto is placed in proximity to a phantom body with said spacer interposed between said device and said body.

3. The electromagnetic radiation exposure protection mechanism according to claim 1, wherein said wireless telecommunications device is provided with a planar antenna having electromagnetic directivity, and said spacer is formed in a direction approximately parallel to the direction of the electromagnetic radiation emanating from said wireless telecommunications device.

4. The electromagnetic radiation exposure protection mechanism according to claim 2, wherein said wireless telecommunications device is provided with a planar antenna having electromagnetic directivity, and said spacer is formed in an approximately parallel direction to the direction of the electromagnetic radiation emanating from said wireless telecommunications device.

5. The electromagnetic radiation exposure protection mechanism according to claim 1, wherein said electromagnetic radiation exposure protection mechanism is a belt clip.

6. The electromagnetic radiation exposure protection mechanism according to claim 2, wherein said electromagnetic radiation exposure protection mechanism is a belt clip.

7. The electromagnetic radiation exposure protection mechanism according to claim 3, wherein said electromagnetic radiation exposure protection mechanism is a belt clip.
